(19) United States
(12) Patent Application Publication
(10) Pub. No.: US 2025/0218739 A1
(43) Pub. Date: Jul. 3, 2025

(54) SUBSTRATE PROCESSING APPARATUS, SUBSTRATE PROCESSING METHOD, AND MANUFACTURING APPARATUS

(71) Applicant: SEMES CO., LTD., Cheonan-si (KR)

(72) Inventors: Joon Hee LEE, Suwon-si (KR); Ki Moon KANG, Yongin-si (KR); Pil Kyun HEO, Yongin-si (KR); Hong Chan CHO, Hwaseong-si (KR); Byeong Kwan KIM, Hwaseong-si (KR); Ji Young CHOI, Hwaseong-si (KR); Joon Ho WON, Suwon-si (KR)

(73) Assignee: SEMES CO., LTD., Cheonan-si (KR)

(21) Appl. No.: 18/984,091

(22) Filed: Dec. 17, 2024

(30) Foreign Application Priority Data
Dec. 28, 2023 (KR) 10-2023-0194229

(51) Int. Cl. H01J 37/32

(52) U.S. Cl. CPC H01J 37/32568; H01J 37/32091; H01J 37/3211; H01J 37/32357; H01J 37/3244; H01J 37/32541; H01J 37/32715; H01J 2237/2007

(57) ABSTRACT

Disclosed is an apparatus for processing a substrate, the apparatus including: a chamber providing a processing space; an electrode unit for generating first plasma in the processing space and having opposing electrodes; a coil unit located in an upper side of the processing space, and for generating second plasma supplied into the processing space; and a remote plasma unit for supplying radicals to the processing space.

### CROSS-REFERENCE TO RELATED APPLICATIONS

This application claims priority to and the benefit of Korean Patent Application No. 10-2023-0194229 filed in the Korean Intellectual Property Office on Dec. 28, 2023, the entire contents of which are incorporated herein by reference.

### TECHNICAL FIELD

The present invention relates to a substrate processing apparatus, a substrate processing method, and a manufacturing apparatus.

### BACKGROUND ART

To manufacture semiconductor devices, various processes, such as deposition, lithography, exposure, development, etching, ashing, cleaning, baking, and ion implantation, are performed on substrates such as wafers.

Among these processes, the coating process or deposition process is a process to form a photoresist film on the substrate, the exposure process is a process to irradiate a photoresist film formed on the substrate through the coating process, deposition process, and the like with light in a pattern shape to change the properties of the light-irradiated portion, and the development process is a process to form a pattern by selectively removing the photoresist film on which the exposure process has been performed. Among them, the application process is a process in which the photoresist is supplied to the substrate in a liquid phase to form a film, and the deposition process is a dry deposition process in which the photoresist is supplied to the substrate in a vapor phase to form a film. In addition, the development process may be divided into a wet method by supplying a liquid developer to the substrate and a dry method by using plasma/radicals, etc.

On the other hand, the above application process, deposition process, and development process are performed in different chambers. Therefore, the user needs to equip separate chambers for each of the above processes, so that the above processes are not efficient.

In addition, there are two types of chambers for generating plasma: Capacitively Coupled Plasma (CCP) type and Inductively Coupled Plasma (ICP) type. Since the advantages of the CCP type chamber and the ICP type chamber are different, in some cases, it may be necessary to process a substrate in a CCP type chamber and an ICP type chamber, separately. In this case, it is time consuming to transfer the substrate from the CCP type chamber to the ICP type chamber, or from the ICP type chamber to the CCP type chamber.

### SUMMARY OF THE INVENTION

The present invention has been made in an effort to provide a substrate processing apparatus, a substrate processing method, and a manufacturing apparatus that are capable of efficiently processing a substrate.

The present invention has also been made in an effort to provide a substrate processing apparatus, a substrate processing method, and a manufacturing apparatus that are capable of performing a deposition process and a development process together on a substrate.

The present invention has also been made in an effort to provide a substrate processing apparatus, a substrate processing method, and a manufacturing apparatus that are capable of improving development uniformity, etch rate, and efficiency of anisotropic etching.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a chamber providing a processing space; an electrode unit configured to generate first plasma in the processing space and having opposing electrodes; a coil unit located in an upper side of the processing space, and configured to generate second plasma supplied into the processing space; and a remote plasma unit configured to supply radicals to the processing space

According to the exemplary embodiment, the electrode unit may include: a lower electrode unit configured to support a substrate in the processing space and having a lower electrode that is one of the opposing electrodes; and an upper electrode unit positioned to face the lower electrode unit and having an upper electrode, which is another of the opposing electrodes.

According to the exemplary embodiment, the upper electrode unit may include: a shower head facing the lower electrode unit and having a plurality of holes formed therein; a gas box located on a top side of the shower head and configured to provide a diffusion space in which process gas excited by the first plasma is diffused; and an upper power source, which is a source power source, configured to apply power to the shower head to generate the first plasma in the processing space.

According to the exemplary embodiment, the lower electrode unit may include a lower power source, which is a bias power source, to control a flow of the first plasma, the second plasma, or the radicals to the lower electrode.

According to the exemplary embodiment, the coil unit may include: a plasma chamber located on a top side of the upper electrode unit and configured to provide a plasma excitation space in communication with the processing space; a coil provided to surround the plasma chamber; and a coil power source, which is a source power source, configured to generate the second plasma in the plasma excitation space with the coil.

According to the exemplary embodiment, the remote plasma unit may include: a gas supply channel in communication with the processing space; and a remote plasma generating unit configured to generate plasma, trapping ions from the plasma, and selectively supplying the radicals contained in the plasma into the gas supply channel.

According to the exemplary embodiment, the apparatus may further include a controller configured to control the electrode unit, the coil unit, and a remote plasma unit, in which the controller may control the coil unit and the electrode unit to generate the first plasma and the second plasma during processing of one substrate.

the aa, the apparatus may further include a controller configured to control the electrode unit, the coil unit, and a remote plasma unit, in which the controller may control any one of the remote plasma unit, the electrode unit, and the coil unit to process the substrate by at least one of the first plasma and the second plasma and then process the substrate with the radicals.

According to the exemplary embodiment, the apparatus may further include a controller configured to control the electrode unit, the coil unit, and a remote plasma unit, in which the controller may control at least one of the electrode unit, the coil unit, and the remote plasma unit to selectively generate the first plasma, the second plasma, and the radicals, according to a film removal profile required for the substrate being processed in the processing space.

According to the exemplary embodiment, the apparatus may further include a gas supply unit configured to supply process gas to the processing space, in which the gas supply unit may include: a first gas supply source configured to supply organometallic precursors and/or reverse reactants to the processing space; and a second gas supply source configured to supply development chemical materials and carrier gas to the processing space.

According to the exemplary embodiment, the remote plasma unit may include a third gas supply source supplying hydrogen gas, halogen gas, and/or carrier gas to the remote plasma generating unit.

Another exemplary embodiment of the present invention provides a method of processing a substrate, the method including: loading a substrate into a processing space of a chamber; and continuously processing the substrate in the processing space by using first plasma generated by a Capacitively Coupled Plasma (CCP) manner, and second plasma that is generated by an Inductively Coupled Plasma (ICP) manner and is supplied to the processing space.

According to the exemplary embodiment, the first plasma may be generated by opposing electrodes oppositely disposed with the substrate interposed between the opposing electrodes, and the second plasma may be generated by a coil positioned closer to an edge region of the substrate than to a center region of the substrate when viewed from above.

According to the exemplary embodiment, the substrate may be further processed by supplying radicals into the processing space after processing the substrate by the first plasma and the second plasma.

According to the exemplary embodiment, a deposition process may be performed to supply deposition gas from the processing space to the substrate to form a film on the substrate.

According to the exemplary embodiment, a development process may be performed to remove the film formed by the deposition process by using the first plasma and the second plasma.

According to the exemplary embodiment, the film formed by the deposition gas may be formed from a material containing a photoresist.

Still another exemplary embodiment of the present invention provides a manufacturing apparatus including: a chamber having a processing space; a lower electrode unit configured to support a substrate in the processing space, and having a lower electrode; an upper electrode unit positioned to face the lower electrode unit, including an upper electrode that is an opposing electrode of the lower electrode, and configured to generate first plasma in the processing space; a coil unit configured to generate second plasma in a plasma excitation space positioned at an upper side of the processing space, and supplying the second plasma to the processing space, the plasma excitation space being in fluid communication with the processing space; a remote plasma unit configured to supply radicals to the processing space via the plasma excitation space; a gas supply unit configured to supply process gas to the processing space through the plasma excitation space; and an exhaust unit configured to exhaust the processing space.

According to the exemplary embodiment, the lower electrode unit may include: a chucking electrode configured to chuck the substrate with electrostatic force; a temperature switching box configured to selectively supply a fluid of a first temperature, and a fluid of a second temperature having a temperature higher than the first temperature, to a flow path formed in the lower electrode; and a chiller configured to supply the temperature switching box with the fluid of the first temperature or the fluid of the second temperature having the temperature higher than the first temperature, and the chamber may have a heater buried therein, the chamber may be equipped with a pressure gauge for measuring a pressure in the processing space, and the exhaust unit may further include an exhaust flow rate control valve for regulating an exhaust flow rate from the processing space based on a measurement value of the pressure gauge.

According to the exemplary embodiment, the manufacturing apparatus may further include a controller, in which the controller may control the heater such that a temperature of the chamber is maintained at a set temperature of 100° C. or higher during processing of the substrate, and the controller may control the temperature switching box so that during the processing of the substrate, the temperature switching box supplies a fluid of −70° C. to 90° C. into the flow path, and supplies a fluid of −30° C. to 200° C. to the flow path after the processing of the substrate is terminated, and after the processing of the substrate is terminated, the temperature switching box supplies a fluid of a higher temperature than a temperature during the processing of the substrate.

According to the exemplary embodiment of the present invention, it is possible to effectively process a substrate.

Further, according to the exemplary embodiment of the present invention, it is possible to uniformly exhaust airflow around a substrate.

Further, according to the exemplary embodiment of the present invention, it is possible to effectively recover and exhaust a treatment liquid supplied to a substrate and fume generated by the supply of the treatment liquid.

Further, according to the exemplary embodiment of the present invention, it is possible to maintain a constant exhaust flow rate per unit time for airflow around the substrate, even when bowls are lifted to change a liquid recovery path.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a substrate processing apparatus according to an exemplary embodiment of the present invention.

FIG. 2 is a diagram illustrating an electrode unit of the substrate processing apparatus of FIG. 1 generating plasma in a processing space.

FIG. 3 is a diagram illustrating a coil unit of the substrate processing apparatus of FIG. 1 supplying plasma to the processing space.

FIG. 4 is a diagram illustrating a remote plasma unit of the substrate processing apparatus of FIG. 1 supplying radicals into the processing space.

FIG. 5 is a graph illustrating plasma density by region of a substrate when the substrate is processed with the electrode unit of FIG. 1.

FIG. 6 is a graph illustrating the plasma density by region of a substrate when a bias power source applies power to a lower electrode when processing a substrate with the electrode unit of FIG. 1.

FIG. 7 is a diagram illustrating the plasma density by region of a substrate when the substrate is processed with the coil unit after the substrate is processed with the electrode unit of FIG. 1.

FIG. 8 is a diagram illustrating the removal of a film on a substrate when the substrate is processed with the electrode unit of FIG. 1.

FIG. 9 is a diagram illustrating the removal of a film on a substrate when the substrate is processed with the coil unit after the substrate is processed with the electrode unit of FIG. 1.

FIG. 10 is a diagram illustrating a substrate processing apparatus according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

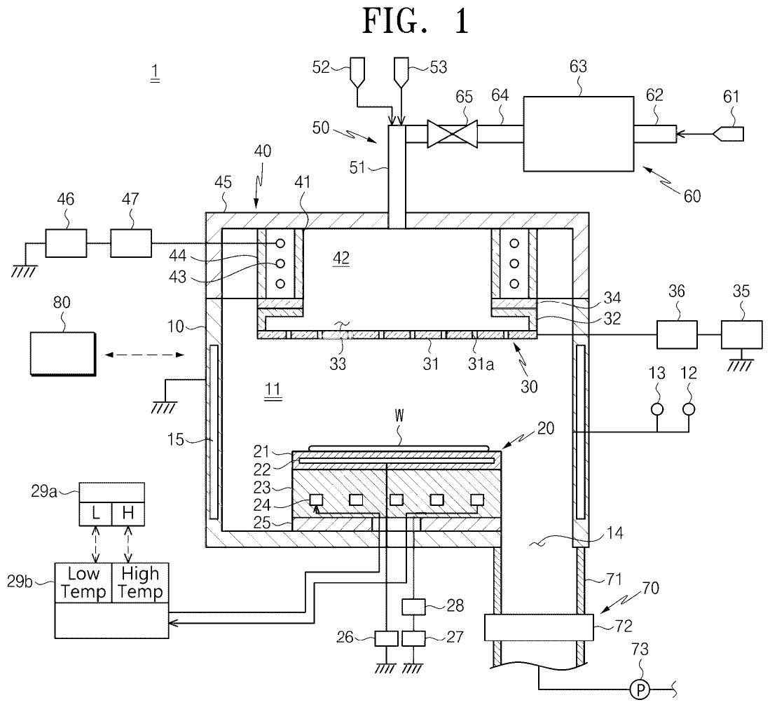

Hereinafter, with reference to FIGS. 1 to 10, a substrate processing apparatus 1 according to an exemplary embodiment of the present invention will be described in detail.

The substrate processing apparatus 1 may be an apparatus for processing a substrate W, which may be a wafer. The substrate processing apparatus 1 may be a semiconductor manufacturing device capable of performing some of the processes required to manufacture a semiconductor device. Further, the substrate processing method described herein may be a semiconductor device manufacturing method for manufacturing a semiconductor device.

FIG. 1 is a diagram illustrating a substrate processing apparatus according to an exemplary embodiment of the present invention.

The substrate processing apparatus 1 may include a chamber 10, a lower electrode unit 20, an upper electrode unit 30, a coil unit 40, a gas supply unit 50, a remote plasma unit 60, an exhaust unit 70, and a controller 80. The lower electrode unit 20 and the upper electrode unit 30 may also be referred to as the electrode units 20 and 30.

The chamber 10 may provide a processing space 11. In the processing space 11, the substrate W may be processed. The chamber 10 may be made of a material that is highly resistant to plasma generated in, or supplied to, the processing space 11. At one side of the chamber 10, an opening (not illustrated) may be formed through which the substrate W may be introduced. Through the opening, the substrate W may be loaded into the processing space 11 or unloaded from the processing space 11. Further, the opening may be blocked or opened by an opening/closing device, which may be referred to as a door, valve, shutter, or the like. Furthermore, the chamber 10 may be grounded.

At the bottom of the chamber 10, an exhaust hole 14 may be formed. The exhaust hole 14 may be connected to the exhaust unit 70 described later. The exhaust hole 14 may transmit the reduced pressure provided by the exhaust unit 70 to the processing space 11. Process gas, plasma, and radicals supplied to the processing space 11 and process by-products generated as the substrate W is processed may be exhausted to the outside of the substrate processing apparatus 1 through the exhaust hole 14 and the exhaust unit 70.

In addition, the chamber 10 may be equipped with a first gauge 12, a second gauge 13, and a heater 15.

The first gauge 12 may be a gauge for measuring the pressure in the processing space 11. The first gauge 12 may be a vacuum Baratron gauge. The first gauge 120 may be a vacuum Baratron gauge that measures pressure as a capacitor thin film electrode distance changes. The first gauge 12 may measure the pressure in the processing space 11 and transmit the measured pressure to the controller 80. Based on the pressure value measured by the first gain 12, the controller 80 may control an exhaust flow rate control valve 72 of the exhaust unit 70 described later.

The second gauge 13 may be a gauge that determines whether the pressure in the processing space 11 is equal to or greater than a set pressure or is less than the set pressure. The second gauge 13 may be a vacuum/atmospheric pressure Baratron gauge. The second gauge 13 determines that the processing space 11 has switched to a normal pressure state when the pressure in the processing space 11 is equal to or greater than the set pressure, and determines that the processing space 11 has switched to a vacuum state when the pressure in the processing space 11 is less than the set pressure. The second gauge 13 may determine whether the state of the processing space 11 is normal pressure or vacuum and transmit a result of the determination to the controller 80. The controller 80 may control the configuration of the substrate processing apparatus 1 to allow the substrate processing apparatus 1 to perform a processing process on the substrate W after the state of the processing space 11 has switched to a vacuum state.

The heater 15 may maintain the temperature of the chamber 10 at a certain temperature or above. For example, the controller 80 may control the heater 15 so that the temperature of the chamber 10 is maintained at or above 100° C. This is to create a vaporizing atmosphere so that process by-products generated from the reaction of halogen gas with an oxide in the processing space 11 do not adhere around an inner wall of the chamber 10 in powder form.

Furthermore, the temperature of the chamber 10 may be kept constant at a set temperature, at a temperature of 100° C. or higher. This is to maintain the temperature of the chamber 10 at the set temperature, thereby preventing the impedance of the chamber 10 from changing as the temperature changes.

The heater 15 may be provided as a sheath heater, a cartridge heater, or the like.

Alternatively, the heater 15 may include a flow path provided in the inner wall of the chamber 10 and a heat exchanger (not illustrated), and the heat exchanger may supply a temperature controlled fluid (e.g., a temperature controlled fluid with a temperature in the range of 100° C. to 120° C.) to the flow path formed in the chamber 10 to maintain the temperature of the chamber 10 at the set temperature, at a temperature at or above 100° C.

The lower electrode unit 20 may support the substrate W in the processing space 11. The lower electrode unit 20 may control the flow of plasma, ions, radicals, etc. introduced into the substrate W. The lower electrode unit 20 may chuck the substrate W.

The lower electrode unit 20 may include a dielectric plate 21, a chucking electrode 22, a lower electrode 23, an insulating member 25, a chucking power source 26, a lower power source 27, a lower matcher 28, a chiller 29a, and a temperature switching box 29b. The chiller 29a and the temperature switching box 29b may also be referred to as chiller modules 29a and 29b.

The dielectric plate 21 may be made of a material including a dielectric. The dielectric plate 21 may be made of a material including a ceramic. The dielectric plate 21 may be a ceramic disk.

The dielectric plate 21 may provide a support surface on which the substrate W may be supported. The dielectric plate 21 may be provided with a chucking electrode 22. The chucking electrodes 22 may receive a voltage applied from the chucking power source 26 to generate electrostatic force. The chucking power source 26 may apply a DC voltage to the chucking electrode 22. When the chucking power source 26 applies a DC voltage, the chucking electrode 22 may be charged to + or −. And, the substrate W may be charged to − or +, the opposite polarity of the chucking electrode 22. When the chucking electrode 22 and the substrate W are charged with opposite polarities, the chucking electrode 22 may attract the substrate W with electrostatic force to the chucking electrode 22, thereby chucking the substrate W. The chucking electrode 22 may be provided as a monopolar or bipolar type.

The bottom electrode 23 may be positioned on the dielectric plate 21 and downstream of the chucking electrode 22. The lower electrode 23 may be connected to a lower power source 27. The lower power source 27 may apply high frequency power to the lower electrode 23. The lower power source 27 may apply RF power to the lower electrode 23. The lower power source 27 may be a bias power source that controls the flow of plasma, ions, radicals, etc. above the substrate W placed on the lower electrode unit 20. The lower power source 27 may apply RF power having a lower frequency than the upper power source 35 and the coil power source 46 described later to the lower electrode 23. The lower electrode 23 may be made of a conductive material. For example, the lower electrode 23 may be made of a metallic material.

Additionally, a lower matcher 28 may be installed between the lower power source 27 and the lower electrode 23 to ensure that the RF power applied by the lower power source 27 is properly applied to the lower electrode 23. The lower matcher 28 may perform impedance matching so that RF power applied by the lower power source 27 may be delivered to the lower electrode 23 with high efficiency.

The lower electrode 23 may have a flow path 24 formed in it. The flow path 24 may be formed in the form of a spiral over the entire region of the lower electrode 23 when viewed from above. In the flow path 24, the chiller modules 29a and 29b may supply a fluid of a first temperature or a fluid of a second temperature, which is a temperature higher than the first temperature.

The chiller modules 29a and 29b may include a chiller 29a and a temperature switching box 29b. The chiller 29a may regulate a temperature of a fluid (which may be, for example, cooling water, cooling gas, heating water, heating gas, or the like) to the first temperature or the second temperature. The chiller 29a may supply the fluid temperature-adjusted to the first temperature or the second temperature to the temperature switching box 29b. The temperature switching box 29b may allow selective supply of the fluid of the first temperature or the fluid of the second temperature into the flow path 24. The first temperature may be between-70 and 30° C. and the second temperature may be between 3° and 90° C. In contrast, the first temperature may be 30 to 90° C. and the second temperature may be 90 to 200° C.

The temperature of the lower electrode 23, and thus of the entire support unit 20, may be adjusted by the fluid supplied to the flow path 24 via the chiller modules 29a and 29b. Fluid supplied to the flow paths 24 via the chiller modules 29a and 29b may be circulated through the flow path 24 and back to the chiller modules 29a and 29b.

While a processing process is being performed on the substrate W, for example, while performing a vapor deposition process or a vaporization process on the substrate W, the chiller modules 29a and 29b may supply a fluid of the first temperature, which is a relatively low temperature, to the flow path 24. This is to realize a more anisotropic photoresist behavior.

After the processing process for the substrate W has ended, for example, after the substrate W has been removed from the processing space 11, to perform an idle clean for the support unit 20, the chiller modules 29a and 29b may supply the fluid of the second temperature, which is a relatively high temperature, to the flow path 24 such that the support unit 200 has a temperature of 100° C.

The insulating member 25 may be provided between the chamber 10 and the lower electrode 23. The insulating member 25 may be made of an insulating material. The insulating member 25 may electrically separate the chamber 10 and the lower electrode 23 which is grounded.

The upper electrode unit 30 may be provided to face the lower electrode unit 20. The upper electrode unit 30 may be provided to face each other with the substrate W placed on the lower electrode unit 20 therebetween. The upper electrode unit 30 may include a shower head 31, a gas box 32, an insulator 34, an upper power source 35, and an upper matcher 36.

The shower head 31 may provide a uniform supply of process gas, plasma, ions, radicals, etc. to the processing space 11. A plurality of holes 31a may be formed in the shower head 31. The plurality of holes 31a may be formed uniformly over the entire region of the shower head 31. The shower head 31 may be made of a conductive material. The shower head 710 may be an upper electrode. The shower head 31 may function as an opposing electrode to the lower electrode 23 described above. The upper power source 35 may apply high frequency power to the shower head 31. The upper power source 35 may apply RF power to the shower head 31. The upper power source 35 may be a source power source that generates plasma in the processing space 11. The upper power source 35 may apply RF power to the shower head 31 at a higher frequency than the lower power source 27 described above.

In addition, the upper matcher 36 may be installed between the upper power source 35 and the shower head 31 to ensure that the RF power applied by the upper power source 35 is properly applied to the shower head 31. The upper matcher 36 may perform impedance matching so that RF power applied by the lower power source 27 may be delivered to the lower electrode 23 with high efficiency.

The gas box 32 may be installed on top of the shower head 31. The gas box 32 may form a diffusion space 33. Process gas supplied by the gas supply unit 50 described hereinafter, radicals supplied by the remote plasma unit 60 described hereinafter, and plasma generated by the coil unit 40 described hereinafter may be supplied to the processing space 11 through the hole 31a formed in the shower head 31. The gas box 32 may be disposed between a plasma excitation space 42 and the shower head 31, to provide the diffusion space 33.

The process gas, radicals, and plasma described above may be introduced into the diffusion space 33 and diffuse primarily in a lateral direction, and the diffused process gas, radicals, and plasma may be introduced into the processing space 11 relatively uniformly through the holes 31a formed in the shower head 31.

Additionally, the gas box 32 may be made of a conductive material. Further, the gas box 32 and the shower head 31 may be electrically connected to each other. In the example described above, the present invention has been described based on the case where the upper power source 35 applies RF power directly to the shower head 31 as an example, but the upper power source 35 may also apply RF power indirectly to the shower head 31 by applying RF power directly to the gas box 32.

The insulator 34 may be disposed between the gas box 32 and the chamber 10. The insulator 34 may electrically separate the gas box 32 with respect to the chamber 10, which is grounded. The insulator 34 may be made of an insulating material.

The lower electrode unit 20 and the upper electrode unit 30 described above may function as opposing electrode units. Plasma may be formed between the lower electrode unit 20 and the upper electrode unit 30, as described later. The plasma generated by the electrode units 20 and 30 in the processing space 11 is defined as first plasma. The first plasma may be the plasma generated by the electrode units 20 and 30 in a CCP manner.

The coil unit 40 may generate plasma at the upper side of the processing space 11. The coil unit 40 may generate plasma at the upper side of the processing space 11 and supply the generated plasma into the diffusion space 33. The plasma supplied into the diffusion space 33 may be supplied into the processing space 11.

The coil unit 40 may include a plasma chamber 41, a coil 43, a seal tube 44, a lead 45, a coil power source 46, and a coil matcher 47.

The plasma chamber 41 may provide a plasma excitation space 42. The plasma excitation space 42 may have a smaller diameter than the processing space 11 when viewed from the top. The plasma chamber 41 may be provided as a cylindrical shaped chamber providing the plasma excitation space 42. The plasma chamber 41 may be made of the same or similar material as the chamber 10 described above. The plasma chamber 41 may be grounded.

The plasma excitation space 42 may be in fluid communication with the diffusion space 33. The diffusion space 33 may be in fluid communication with the processing space 11. Thus, the plasma excitation space 42 may be in indirect fluid communication with the processing space 11.

The coil 43 may be configured to surround the plasma chamber 41. Depending on the shape, shape, thickness, material, etc. of the coil 43, the density of the plasma generated in the plasma excitation space 42 may vary. A user may select any one of the coils 43 having different shapes, geometries, thicknesses, materials, etc. to be installed in the substrate processing apparatus 1 to vary the density of plasma generated in the plasma excitation space 42.

The coil power source may apply high frequency power to the coil 43. The coil power source 46 may apply RF power to the coil 43. The coil power source 46 may be a source power source that generates plasma in the plasma excitation space 42. The coil power source 46 may apply RF power having a higher frequency than the lower power source 27 described above to the coil 43.

Further, the coil matcher 47 may be installed between the coil 43 and the coil power source 46 to ensure that the RF power applied by the coil power source 46 is properly applied to the coil 43. The upper matcher 47 may perform impedance matching so that the RF power applied by the coil power source 46 may be applied to the coil 43 with high efficiency.

The seal tube 44 may be disposed in the plasma chamber 41 and on the outer side of the coil 43. The seal tube 44 may have a cylindrical shape that surrounds the coil 43. The seal tube 44 may function as an RF seal tube that blocks RF fields generated from the coil 43 from radiating outwardly from the coil 43 when RF power is applied to the coil 43.

The lead 45 may be located on the top side of the chamber 10. The lead 45 may be grounded. The lead 45 may be provided to have a structure that covers the plasma chamber 41, the coil 43, and the seal tube 44. The lead 45 may be grounded. The lead 45 may be in contact with the chamber 10 and grounded with the chamber 10.

The coil unit 40 may generate plasma in the plasma excitation space 42. The plasma generated by the coil unit 40 in the plasma excitation space 42 is defined as second plasma. The second plasma may be plasma generated by the coil unit 40 in an ICP manner.

The gas supply unit 50 may supply process gas to the processing space 11. The gas supply unit 50 may include a gas supply line 51 connected to the top center of the lead 45, a first gas supply source 52 supplying first process gas PG1 to the gas supply line 51, and a second gas supply source 53 supplying second process gas PG2 to the gas supply line 51.

The first process gas PG1 and the second process gas PG2 may be pre-supplied into the plasma excitation space 42 and then sequentially supplied into the processing space 11 through the diffusion space 33 and the hole 31a.

The first process gas PG1 may include an organometallic precursor and a reverse reactant. The first process gas PG1 may be deposition gas that may be used to deposit a photoresist film on the substrate W. The first process gas PG1 may be supplied to the processing space 11 at a high temperature and in gas phase to increase the deposition efficiency.

The organometallic precursors may be a predetermined precursor among a wide variety of candidate metal-organic precursors. For example, when M is tin, the precursors include t-butyltris(dimethylamino)tin, i-butyltris(dimethylamino)tin, n-butyltris(dimethylamino)tin, sec-butyltris(dimethylamino)tin, and sec-butyltris(dimethylamino)tin, i-propyl(tris)dimethylamino tin, n-propyl tris(diethylamino)tin, and similar alkyl (tris)(t-butoxy)tin compounds, for example, t-butyl tris(t-butoxy)tin. In some exemplary embodiments, the organometallic precursors may be partially fluorinated.

The reverse reactants may include water, peroxides (e.g., hydrogen peroxide), dihydroxy alcohols or polyhydroxy alcohols, fluorinated dihydroxy alcohols or fluorinated polyhydroxy alcohols, fluorinated glycols, and other sources of hydroxyl moieties.

The first process gas PG1 including an organometallic precursor and a reverse reactant may enter the processing space 11 in a gas phase and form a film (e.g., a photoresist film) on the substrate W.

The second process gas PG2 may include a development chemical material in the gas phase and carrier gas, which is inert gas. For example, the development chemical material may include one or more gas selected from BCl₃, HBr, HCl, H₂, and Cl₂. The inert gas may include one or more gas selected from N2, He, Ne, Ar, Kr, Xe, and Rn.

The remote plasma unit 60 may supply radicals to the processing space 11. The remote plasma unit 60 may include a third gas supply source 61, a first gas supply channel 62, a remote plasma generating unit 63, a second gas supply channel 64, and a remote plasma valve 65.

The third gas supply source 61 may supply hydrogen gas and/or halogen gas to the remote plasma generating unit 63 via the first gas supply channel 62. Furthermore, the third gas supply source 61 may supply carrier gas, which is inert gas, to the remote plasma generating unit 63 via the first gas supply channel 62. The inert gas may be one or more gas selected from N2, He, Ne, Ar, Kr, Xe, and Rn.

The remote plasma generating unit 63 may generate plasma by excitation of gas supplied by the third gas supply source 61 in an ICP or CCP manner. Then, the remote plasma generating unit 63 may trap ions from the generated plasma. That is, the remote plasma generating unit 63 may trap ions among the ions and radicals contained in the plasma, and selectively supply the radicals to the second gas supply channel 64.

The second gas supply channel 64 may be equipped with the remote plasma valve 65, which may be an on/off valve or a flow rate regulating valve. The second gas supply channel 64 may be connected to the gas supply line 51 described above. Radicals supplied by the remote plasma generating unit 63 may be supplied to the processing space 11 via the gas supply line 51, the plasma excitation space 42, the diffusion space 33 and the hole 31a.

The exhaust unit 70 may exhaust the atmosphere of the processing space 11. The exhaust unit 70 may exhaust the processing space 11 to exhaust process gas, plasma, and radicals supplied to the processing space 11 from the processing space 11. In addition, the exhaust unit 70 may exhaust process byproducts generated by the processing of the substrate W in the processing space 11 from the processing space 11.

The exhaust unit 70 may include an exhaust pipe 71, an exhaust flow rate control valve 72, and a pump 73.

The exhaust pipe 71 may be connected to the exhaust hole 14 described above. The exhaust flow rate control valve 72 may be installed in the exhaust pipe 71. The exhaust flow rate control valve 72 may be a valve that regulates the exhaust flow rate per unit time to the processing space 11. The exhaust flow rate control valve 72 may be an Auto Pressure Control Valve (APCV). The exhaust flow rate control valve 72 may be provided as a symmetrical type or a butterfly type. The opening and closing rate of the exhaust flow rate control valve 72 may vary based on a pressure measurement value of the first gauge 12 transmitted to the controller 80. For example, when the pressure in the first gauge 12 is lower than a desired pressure, the exhaust flow rate control valve 72 may have a smaller opening and closing rate, and when the pressure in the first gauge 12 is higher than the desired pressure, the flow rate control valve 72 may have a larger opening and closing rate.

The pump 73 may provide a reduced pressure to the processing space 11 via the exhaust pipe 71. The pump 73 may be a turbo pump, or a dry pump. Additionally, the pump 73 may be provided in plurality, such that one pump is provided as a turbo pump and the other is provided as a dry pump. When the plurality of pumps 73 is provided, pumping may be performed by placing a turbo pump upstream, which has excellent pumping performance, and a dry pump downstream. The exhaust gas exhausted through the pump 73 may be delivered to a scrubber and post-processed in the scrubber.

The controller 80 may control the configurations of the substrate processing apparatus 1. For example, the controller 80 may control at least one of the heater 15, the lower electrode unit 20, the upper electrode unit 40, the coil unit 40, the gas supply unit 50, the remote plasma unit 60, the first gauge 12, the second gauge 13, and the exhaust unit 70.

The controller 80 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

In the following, modes of operation of the substrate processing apparatus 1 according to the exemplary embodiment of the present invention will be described.

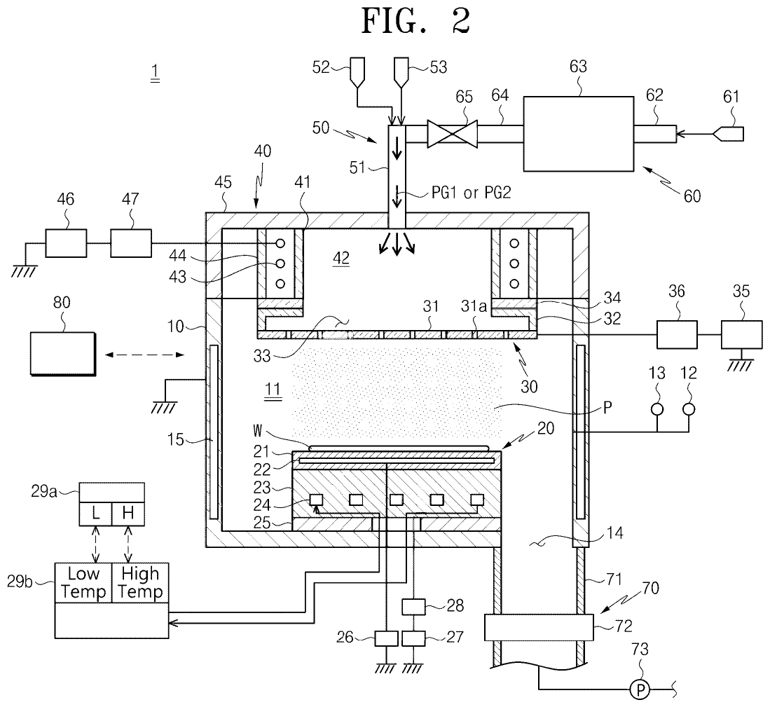

FIG. 2 is a diagram illustrating the electrode unit of the substrate processing apparatus of FIG. 1 generating plasma in the processing space.

FIG. 2 illustrates the case where the substrate processing apparatus 1 is in the CCP mode. When the substrate processing apparatus 1 is in the CCP mode, the gas supply unit 50 may supply process gas to the processing space 11, and the upper power source 35, which is the source power source, may apply RF power to the upper electrode, the shower head 31. At this time, plasma P (first plasma) is formed in the space between the opposing electrodes, the shower head 31 and the lower electrode 23.

When the substrate processing apparatus 1 is in the CCP mode, the lower power source 27, which is a bias power source, may apply RF power to the lower electrode 23 to control the flow of the plasma P above the substrate W. For example, when the lower power source 27 applies RF power to the lower electrode 23, ions or radicals contained in the plasma P may be accelerated and drawn into the substrate W.

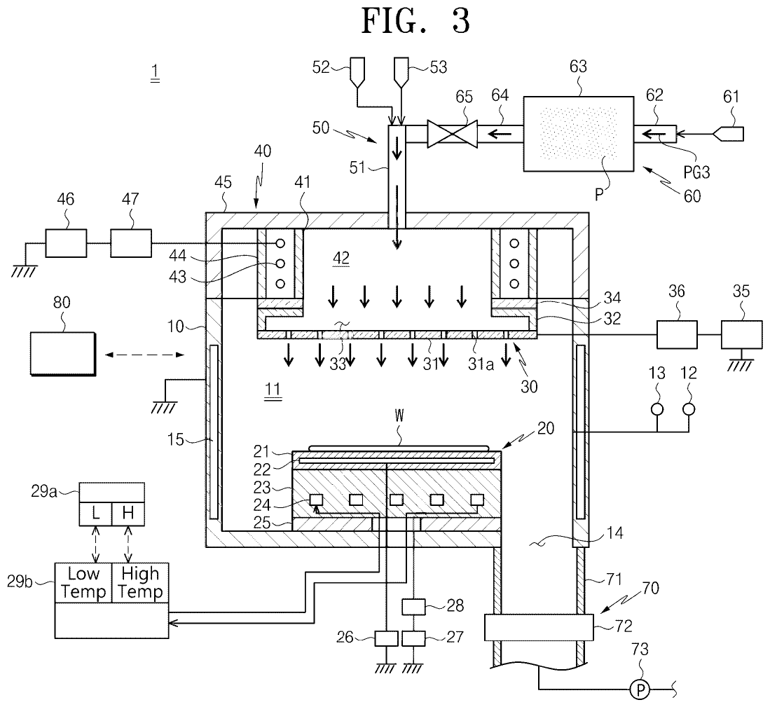

FIG. 3 is a diagram illustrating the coil unit of the substrate processing apparatus of FIG. 1 supplying plasma to the processing space.

FIG. 3 illustrates the case where the substrate processing apparatus 1 is in a remote mode. When the substrate processing apparatus 1 is in the remote mode, the third gas supply source 61 supplies process gas to the remote plasma generating unit 63, and the remote plasma generating unit 63 excites the process gas to generate plasma. The remote plasma generating unit 63 may then trap ions in the generated plasma to select radicals. The selected radicals may be supplied to the processing space 11 via the second gas supply channel 64, the gas supply line 51, the plasma excitation space 42, the diffusion space 33, and the hole 31a.

When the substrate processing device 1 is in the remote mode, the lower power source 27, which is a bias power source, may apply RF power to the lower electrode 23 to control the flow of plasma P above the substrate W as needed. For example, when the lower power source 27 applies RF power to the lower electrode 23, the flow of radicals may be changed.

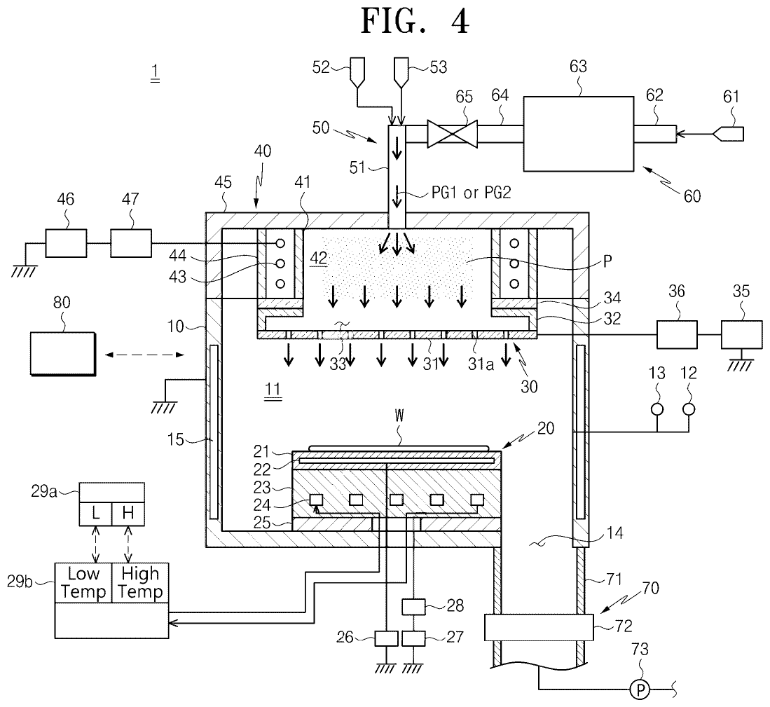

FIG. 4 is a diagram illustrating the remote plasma unit of the substrate processing apparatus of FIG. 1 supplying radicals into the processing space.

FIG. 4 illustrates the case where the substrate processing apparatus 1 is in the ICP mode. When the substrate processing apparatus 1 is in the ICP mode, the gas supply unit 50 supplies process gas to the processing space 11, and the coil power source 46, which is a source power source, may apply RF power to the coil 43. When RF power is applied to the coil 43, an RF electric field is formed in the plasma excitation space 42, and the formed RF electric field may excite the process gas to generate plasma P (second plasma). The plasma P generated in the plasma excitation space 42 may be supplied to the processing space 11 via the diffusion space 33 and the hole 31a.

When the substrate processing device 1 is in the ICP mode, the lower power source 27, which is a bias power source, may apply RF power to the lower electrode 23 to control the flow of plasma P above the substrate W as needed. For example, when the lower power source 27 applies RF power to the lower electrode 23, ions or radicals contained in the plasma P may be accelerated and drawn into the substrate W.

Hereinafter, a method of processing a substrate W by using a substrate processing apparatus 1 according to an exemplary embodiment of the present invention will be described.

The substrate processing apparatus 1 may perform both a deposition process and a development process on the substrate W. The deposition process may be a dry deposition process (vapor phase deposition process). The development process may be a dry development process (vapor phase development process).

The deposition process may include supplying, by the first gas supply source 52, first process gas PG1 to the processing space 11. The first process gas PG1 supplied by the first gas supply source 52 may be supplied to the processing space 11 in a gas phase. The first process gas PG1 supplied to the processing space 11 may be delivered to the substrate W to form a film on an upper surface of the substrate W. The film may be formed from a material including a photoresist.

In the deposition process, the remote plasma unit 60 may be used to improve the deposition rate as needed. While the deposition process is being performed, the remote plasma unit 60 may form neutral radicals and supply the generated radicals into the processing space 11. The radicals help to sufficiently activate the first process gas PG1. The radicals maximize the decomposition of the first process gas PG1, which may improve the deposition rate. When plasma P other than radicals is used in the deposition process, the positive ions of plasma P may collide with the substrate W and damage the thin film. Therefore, in the deposition process, the deposition of the photoresist film may be performed by using only the chemical reaction of radicals through the remote plasma unit 60.

Furthermore, the third gas supply source 61 may supply the first process gas PG1 to the remote plasma generating unit 63, and form radicals from the supplied first process gas PG1 and supply the formed radicals to the processing space 11. Since the radicals are in an unstable state, the radicals may be easily deposited on the substrate W. This allows the deposition of a photoresist film on the substrate W to be realized.

In the developing process, the developing process may be performed on the photoresist film deposited in the deposition process. In one example, after the deposition process described above is performed in the substrate processing apparatus 1, the substrate is taken out of the substrate processing apparatus 1 and exposed to an exposure treatment, the exposed substrate W is loaded into the substrate processing apparatus 1, and the substrate processing apparatus 1 performs a development process on the substrate W.

The development process may be performed by using the electrode units 20 and 30, the coil unit 40, and the remote plasma unit 60. More specifically, a development process may be performed in which plasma and radicals generated by the electrode units 20 and 30, the coil unit 40, and the remote plasma unit 60 are delivered to the photoresist film formed on the substrate W to selectively remove the photoresist film.

When the electrode units 20 and 30 and the coil unit 40 perform the development process by generating the first plasma and the second plasma, the second gas supply source 53 of the gas supply unit 50 may supply the second process gas PG2 including the development chemical material and the carrier gas to the plasma excitation space 42.

In addition, when the remote plasma unit 60 performs the development process by generating radicals, process gas including hydrogen gas, halogen gas, and carrier gas may be supplied to the remote plasma generating unit 63.

Since the substrate processing apparatus 1 is equipped with the electrode units 20 and 30, the coil unit 40, and the remote plasma unit 60, the substrate W may be processed by utilizing the advantages of each unit.

FIG. 5 is a graph illustrating plasma density by region of a substrate when the substrate is processed with the electrode unit of FIG. 1.

The electrode units 20 and 30 may be plasma sources that generate first plasma of the CCP type. The process gas supplied through the gas supply unit 50 is mainly supplied to the central region of the processing space 11. Therefore, the density of the first plasma generated by the electrode units 20 and 30 is highest in the central region of the substrate W (around 150 mm on a 300 mm wafer) and lower in the edge regions of the substrate W.

In other words, since the density of the CCP type first plasma is relatively high in the center region of the substrate W, the development rate may be different in the center region and the edge region of the substrate W.

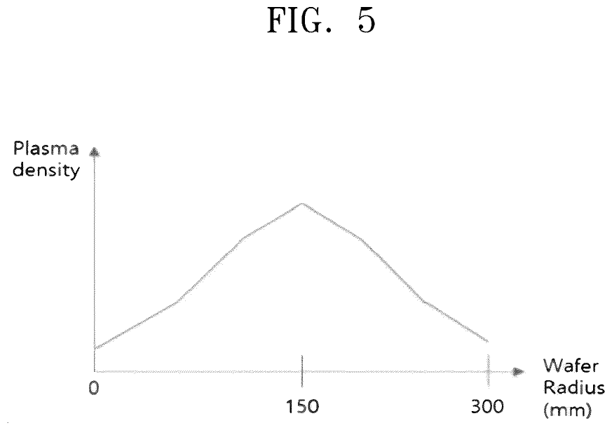

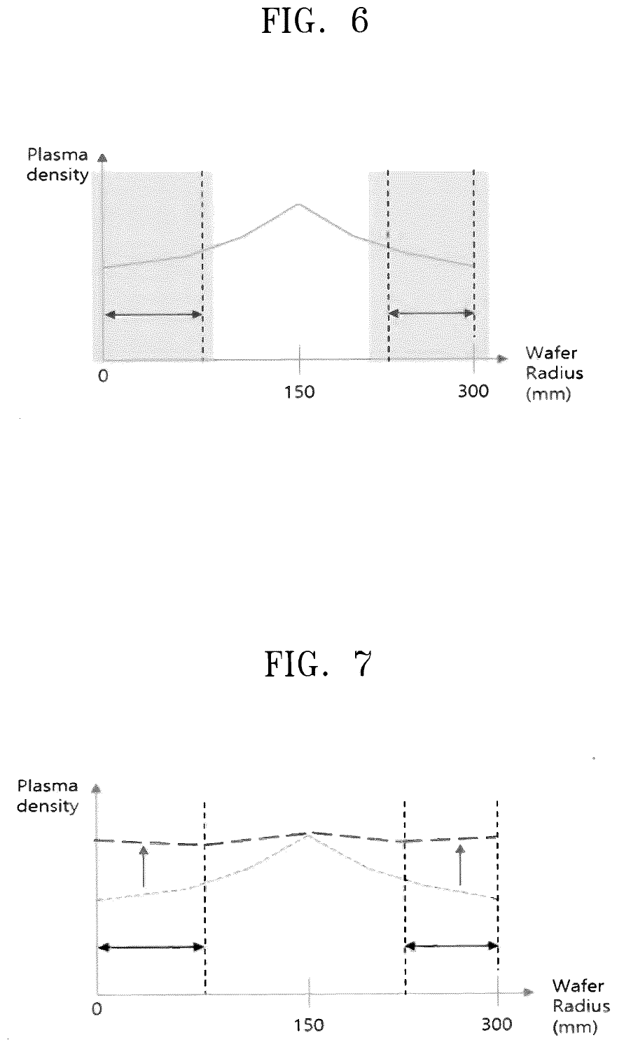

FIG. 6 is a graph illustrating the plasma density by region of a substrate when a bias power source applies power to the lower electrode when processing a substrate with the electrode unit of FIG. 1.

FIG. 6 illustrates the density of the first plasma for each region of the substrate W when the lower power source 27, which is a bias power source, applies RF power to the lower electrode 23 when performing a development process on the substrate W by generating the first plasma through the electrode units 20 and 30. When the lower power source 27 applies RF power to the lower electrode 23, the energy with which the ions contained in the first plasma are attracted to the substrate W (ionization energy) may be higher. In the edge regions of the substrate W, ions are attracted from a greater variety of directions than in the central region of the substrate W. In other words, with the higher ionization energy, the density of the first plasma in the edge regions of the substrate W increases relatively more than in the central region of the substrate W.

In other words, when the lower power source 27 is further controlled independently of the upper power source 35, the plasma density deviation between the center region and the edge region of the substrate W is reduced, as illustrated in FIG. 6. This allows the variation in the development rate of different regions of the substrate W to be mitigated.

FIG. 7 is a diagram illustrating the plasma density by region of a substrate when the substrate is processed with the coil unit after the substrate is processed with the electrode unit of FIG. 1.

The second plasma generated by the coil unit 40 in the plasma excitation space 42 is introduced into the processing space 11 through the diffusion space 33 and the hole 31a. The coil 43 of the coil unit 40 may be configured so that, when viewed from above, the coil 43 is positioned closer to the edge region than to the center region of the substrate W placed in the processing space 11. Furthermore, the process gas supplied by the gas supply unit 50 may not be all excited in the plasma excitation space 42, and some of the process gas may be introduced into the processing space 11.

Therefore, among the second plasma and process gas introduced into the processing space 11, the second plasma and process gas present in the vicinity of the edge region of the substrate W may be further affected by the RF electric field generated by the coil 43. That is, when the coil unit 40 generates the second plasma and supplies the generated second plasma to the processing space 11, the plasma density is relatively high in the edge region of the substrate W compared to the first plasma.

Therefore, in the present invention, after performing the development process on the substrate W with the first plasma generated by the CCP type electrode units 20 and 30, the development process on the substrate W with the second plasma generated by the ICP type coil unit 40 may be further performed to mitigate the deviation in the development rate of the substrate W by region. Furthermore, the processing by the first plasma and the second plasma may be performed continuously before the substrate W is loaded into and unloaded from the processing space 11.

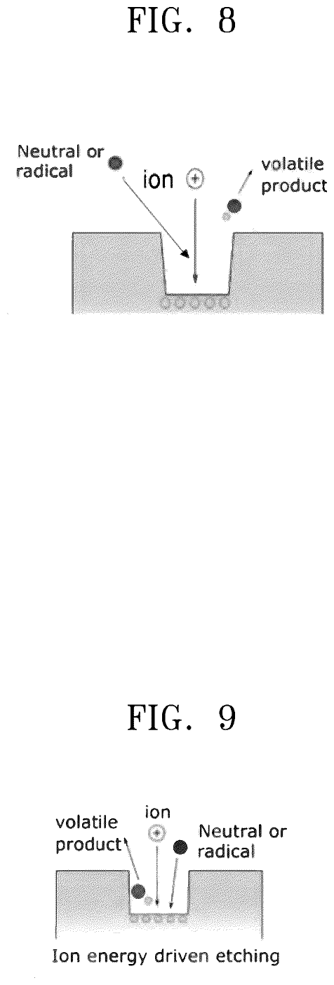

FIG. 8 is a diagram illustrating the removal of a film on a substrate when the substrate is processed with the electrode unit of FIG. 1, and FIG. 9 is a diagram illustrating the removal of a film on a substrate when the substrate is processed with the coil unit after the substrate is processed with the electrode unit of FIG. 1.

Referring to FIGS. 8 and 9, it may be seen that more complete anisotropy in the removal of the film on the substrate W may be realized when the substrate W is processed with the electrode units 20 and 30 and then further processed with the coil unit 40 than the case of removing the film on the substrate W only with the electrode units 20 and 30.

Furthermore, the ions contained in the plasma have relatively high energy. Therefore, the flatness of the film may deteriorate after the film has been processed by the plasma.

Therefore, the present invention may perform post-processing by radicals generated by the remote plasma unit 60 after processing the film of the substrate W with the first plasma and/or the second plasma. In this case, the film flatness deteriorated by the plasma may be further improved.

In the above example, the present invention has been described based on the case where the substrate W is processed with the first plasma and then is processed with the second plasma as an example, but is not limited thereto.

Alternatively, after processing the substrate W with the second plasma, the substrate W may be processed with the first plasma. Furthermore, the substrate W may be processed with only any one of the first plasma or the second plasma.

Further, the substrate W may be processed with radicals after the substrate W is processed with the first plasma, or the substrate W may be processed with radicals after the substrate W is processed with the second plasma.

Whether the substrate W is processed with any processing fluid among the first plasma, the second plasma, or the radicals may depend on the required film removal profile for the substrate W.

For example, when the film removal profile for the substrate W is required to be high in the central region of the substrate W, the substrate W may be processed using only the first plasma. When the film removal profile for the substrate W is required to be high at the edge regions of the substrate W, the substrate W may be processed using only the second plasma. When the film removal profile for the substrate W is required to be uniform by each region of the substrate W, the substrate W may be processed using both first and second plasma.

When the thickness of the film to be removed from the substrate W is small, or when the hardness of the formed film is low, and damage to the film is a concern, the substrate W may be processed with radicals alone.

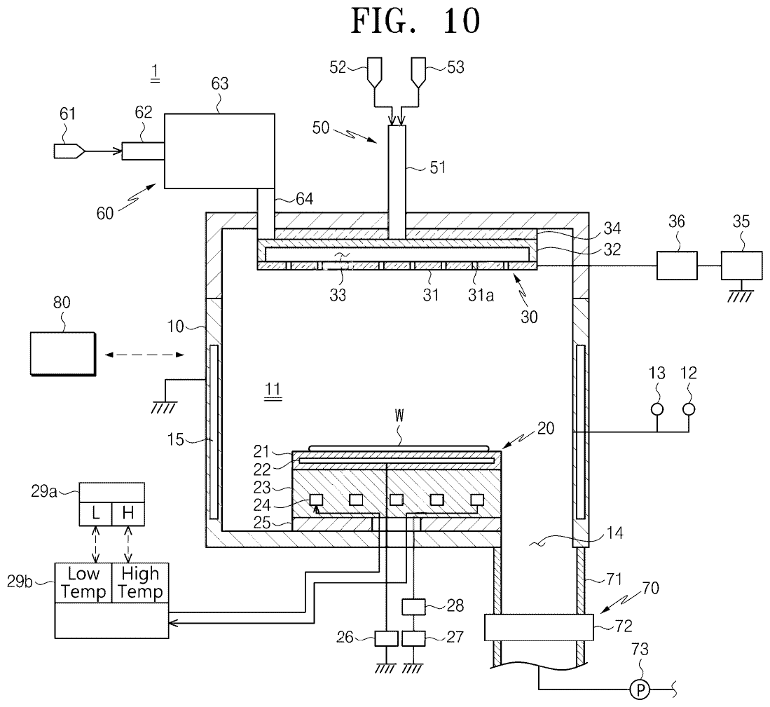

In the above example, the present invention has been described based on the case where the substrate processing apparatus 1 includes both the electrode unit 20, 30, the coil unit 40, and the remote plasma unit 60, but is not limited thereto. For example, as illustrated in FIG. 10, the substrate processing apparatus 1 may include only the electrode units 20 and 30 and the remote plasma unit 60.

Although not illustrated, in other exemplary embodiments, the substrate processing apparatus 1 may also include only the coil unit 40 and the remote plasma unit 60.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for processing a substrate, the apparatus comprising:
a chamber providing a processing space;
an electrode unit configured to generate first plasma in the processing space and having opposing electrodes;
a coil unit located in an upper side of the processing space, and configured to generate second plasma supplied into the processing space; and
a remote plasma unit configured to supply radicals to the processing space.

2. The apparatus of claim 1, wherein the electrode unit includes:
a lower electrode unit configured to support a substrate in the processing space and having a lower electrode that is one of the opposing electrodes; and
an upper electrode unit positioned to face the lower electrode unit and having an upper electrode, which is another of the opposing electrodes.

3. The apparatus of claim 2, wherein the upper electrode unit includes:
a shower head facing the lower electrode unit and having a plurality of holes formed therein;
a gas box located on a top side of the shower head and for providing a diffusion space in which process gas excited by the first plasma is diffused; and
an upper power source, which is a source power source, for applying power to the shower head to generate the first plasma in the processing space.

4. The apparatus of claim 3, wherein the lower electrode unit includes a lower power source, which is a bias power source, to control a flow of the first plasma, the second plasma, or the radicals to the lower electrode.

5. The apparatus of claim 2, wherein the coil unit includes:
a plasma chamber located on a top side of the upper electrode unit and configured to provide a plasma excitation space in communication with the processing space;
a coil provided to surround the plasma chamber; and
a coil power source, which is a source power source, configured to generate the second plasma in the plasma excitation space with the coil.

6. The apparatus of claim 1, wherein the remote plasma unit includes:
a gas supply channel in communication with the processing space; and
a remote plasma generating unit configured to generate plasma, trapping ions from the plasma, and selectively supplying the radicals contained in the plasma into the gas supply channel.

7. The apparatus of claim 1, further comprising:
a controller configured to control the electrode unit, the coil unit, and a remote plasma unit,
wherein the controller controls the coil unit and the electrode unit to generate the first plasma and the second plasma during processing of one substrate.

8. The apparatus of claim 1, further comprising:
a controller configured to control the electrode unit, the coil unit, and a remote plasma unit,
the controller controls any one of the remote plasma unit, the electrode unit, and the coil unit to process the substrate by at least one of the first plasma and the second plasma and then process the substrate with the radicals.

9. The apparatus of claim 1, further comprising:
a controller configured to control the electrode unit, the coil unit, and a remote plasma unit,
the controller controls at least one of the electrode unit, the coil unit, and the remote plasma unit to selectively generate the first plasma, the second plasma, and the radicals, according to a film removal profile required for the substrate being processed in the processing space.

10. The apparatus of claim 1, further comprising:
a gas supply unit configured to supply process gas to the processing space,
wherein the gas supply unit includes:
a first gas supply source configured to supply organometallic precursors and/or reverse reactants to the processing space; and
a second gas supply source configured to supply development chemical materials and carrier gas to the processing space.

11. The apparatus of claim 6, wherein the remote plasma unit includes a third gas supply source supplying hydrogen gas, halogen gas, and/or carrier gas to the remote plasma generating unit.

12. (canceled)

13. (canceled)

14. (canceled)

15. (canceled)

16. (canceled)

17. (canceled)

18. A manufacturing apparatus comprising:
a chamber having a processing space;
a lower electrode unit configured to support a substrate in the processing space, and having a lower electrode;
an upper electrode unit positioned to face the lower electrode unit, including an upper electrode that is an opposing electrode of the lower electrode, and configured to generate first plasma in the processing space;
a coil unit configured to generate second plasma in a plasma excitation space positioned at an upper side of the processing space, and supplying the second plasma to the processing space, the plasma excitation space being in fluid communication with the processing space;
a remote plasma unit configured to supply radicals to the processing space via the plasma excitation space;
a gas supply unit configured to supply process gas to the processing space through the plasma excitation space; and
an exhaust unit configured to exhaust the processing space.

19. The manufacturing apparatus of claim 18, wherein the lower electrode unit includes:
a chucking electrode configured to chuck the substrate with electrostatic force;
a temperature switching box configured to selectively supply a fluid of a first temperature, and a fluid of a second temperature having a temperature higher than the first temperature, to a flow path formed in the lower electrode; and
a chiller configured to supply the temperature switching box with the fluid of the first temperature or the fluid of the second temperature having the temperature higher than the first temperature, and
the chamber has a heater buried therein,
the chamber is equipped with a pressure gauge for measuring a pressure in the processing space, and
the exhaust unit further includes an exhaust flow rate control valve for regulating an exhaust flow rate from the processing space based on a measurement value of the pressure gauge.

20. The manufacturing apparatus of claim 19, further comprising:
a controller,
wherein the controller controls the heater such that a temperature of the chamber is maintained at a set temperature of 100° C. or higher during processing of the substrate, and
the controller controls the temperature switching box so that during the processing of the substrate, the temperature switching box supplies a fluid of −70° C. to 90° C. into the flow path, and supplies a fluid of −30° C. to 200° C. to the flow path after the processing of the substrate is terminated, and after the processing of the substrate is terminated, the temperature switching box supplies a fluid of a higher temperature than a temperature during the processing of the substrate.
